(19) United States
(12) Patent Application Publication
(10) Pub. No.: US 2009/0196093 A1
(43) Pub. Date: Aug. 6, 2009

(54) STACKED DIE MEMORY

(75) Inventors: Thomas Happ, Dresden (DE); Jan Boris Philipp, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 12/023,630

(22) Filed: Jan. 31, 2008

(51) Int. Cl. G11C 11/00; H01L 21/02

(52) U.S. Cl. 365/163; 438/129; 438/102; 257/E21.002

(57) ABSTRACT

A memory includes a first die including a first array of phase change memory cells and a second die including a second array of phase change memory cells. The second die is stacked above the first die. The memory includes lines configured to access the first die and the second die. The first die and the second die are enclosed in a single package.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state—“set”—and from the crystalline state to the amorphous state—“reset”—in response to temperature changes. The temperature changes of the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The temperature in the phase change material in each memory cell generally corresponds to the applied level of current and/or voltage to achieve the heating.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

The maximum storage capacity of a phase change memory should be increased to meet the demands of emerging applications. As the maximum storage capacity is increased, the phase change memory should maintain compatibility with previous phase change memories with respect to data format and access protocols.

For these and other reasons, there is a need for the present invention.

### SUMMARY

One embodiment provides a memory. The memory includes a first die including a first array of phase change memory cells and a second die including a second array of phase change memory cells. The second die is stacked above the first die. The memory includes lines configured to access the first die and the second die. The first die and the second die are enclosed in a single package.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a block diagram illustrating one embodiment of a memory device.

FIG. 3 is a diagram illustrating one embodiment of a memory chip.

FIG. 4 is a block diagram illustrating another embodiment of a memory device.

FIG. 5 is a block diagram illustrating one embodiment of a memory chip enable circuit.

FIG. 6 is a block diagram illustrating another embodiment of a memory device.

FIG. 7 is a block diagram illustrating another embodiment of a memory device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

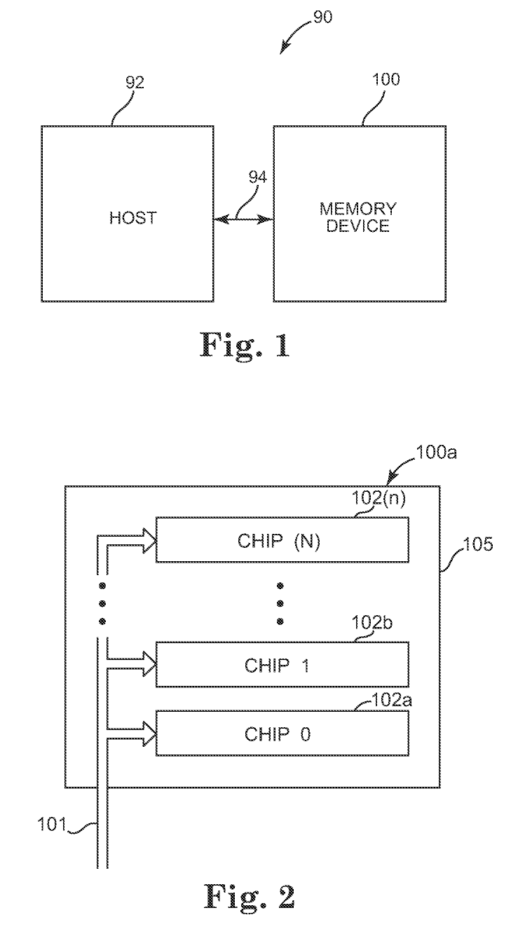

FIG. 1 is a block diagram illustrating one embodiment of a system 90. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player, digital camera), or any other suitable device that uses memory. Memory device 100 provides memory for host 92. In one embodiment, memory device 100 includes a phase change memory device or other suitable resistive or resistivity changing material memory device.

Memory device 100 includes a stacked die memory. The stacked die memory includes a stack of individual memory chips or dies combined into a single package or housing. The individual memory chips are combined in the single package to provide a memory device that is compatible with a single chip memory device with respect to data format and access protocols. In one embodiment, the stacked die memory includes substantially identical memory chips. In another embodiment, the stacked die memory includes one memory chip including a controller and input/output logic and other memory chips that do not include a controller or input/output logic.

As used herein, the term “electrically coupled” is not meant to mean that the elements must be directly coupled together and intervening elements may be provided between the “electrically coupled” elements.

FIG. 2 is a block diagram illustrating one embodiment of a memory device 100a. In one embodiment, memory device 100a provides memory device 100 previously described and illustrated with reference to FIG. 1. Memory device 100a includes chips 102a-102(n), where “n” is an integer indicating a suitable number of chips. Each chip 102a-102(n) is electrically coupled to an external device via communication path 101. Chips 102a-102(n) are enclosed in packaging material or housing 105.

Each chip 102a-102(n) is substantially identical (i.e., identical in fabrication, but not in configuration) and includes an array of phase change memory cells, a controller, input/output logic, and other suitable circuits for accessing the array of phase change memory cells. Each chip 102a-102(n) is stacked on top of or above the previous chip 102a-102(n), such that chip 102b is stacked on top of or above chip 102a. In one embodiment, memory device 100a includes two chips 102a and 102b. In other embodiments, memory device 100a includes any suitable number of chips.

Communication path 101 provides power lines, control lines, address lines, and data lines to each chip 102a-102(n) for providing power, control signals, address signals, and data signals to each chip 102a-102(n) in parallel. Therefore, all signals on communication path 101 to and from an external device are routed to each chip 102a-102(n) in parallel. In one embodiment, each chip 102a-102(n) is selected for read or write access based on a memory address provided on communication path 101. One or more of the bits of the memory address are interpreted by each chip 102a-102(n) as chip select bits. Each chip 102a-102(n) compares the chip select bits to the chip's own identity to determine whether the chip should be selected for the given address range. The identity of each chip 102a-102(n) is programmed using laser fuses, electrical fuses, non-volatile memory cells, such as phase change memory cells, or by using another suitable configuration device. The identity of each chip 102a-102(n) is programmed during a chip level test of each individual chip 102a-102(n) or during a test of memory device 100a after the individual chips 102a-102(n) are combined in housing 105.

In operation, a host, such as host 92 previously described and illustrated with reference to FIG. 1, accesses memory device 100a through communication path 101 for read and write operations. From the perspective of host 92, memory device 100a acts as a single chip memory device and does not require special printed circuit board layouts and/or sideboard connectors. The maximum storage capacity of memory device 100a, however, can be substantially increased compared to a single chip memory device.

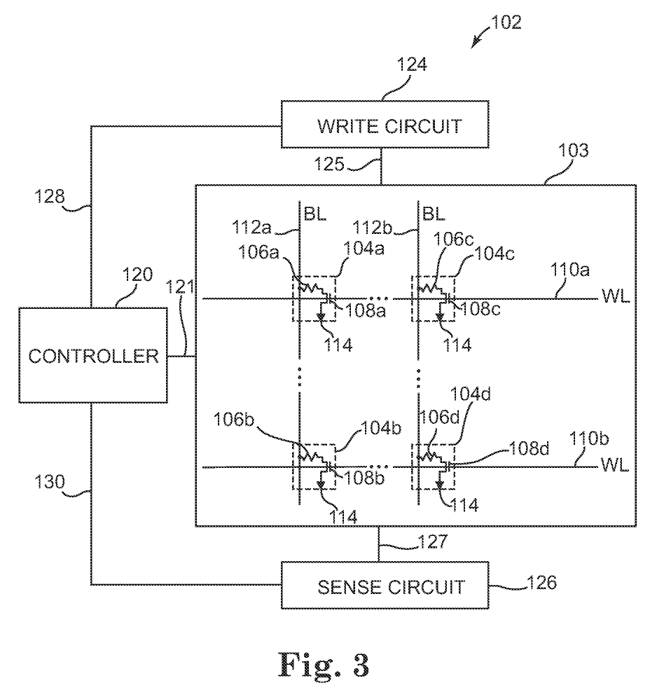

FIG. 3 is a diagram illustrating one embodiment of a memory chip 102. In one embodiment, memory chip 102 provides each memory chip 102a-102(n) previously described and illustrated with reference to FIG. 2. Memory chip 102 includes a write circuit 124, a controller 120, a memory array 103, and a sense circuit 126. Memory array 103 includes a plurality of phase change memory cells 104a-104d (collectively referred to as phase change memory cells 104), a plurality of bit lines (BLs) 112a-112b (collectively referred to as bit lines 112), and a plurality of word lines (WLs) 110a-110b (collectively referred to as word lines 110).

Memory array 103 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130. Each phase change memory cell 104 is electrically coupled to a word line 110, a bit line 112, and a common or ground 114. Phase change memory cell 104a is electrically coupled to bit line 112a, word line 110a, and common or ground 114, and phase change memory cell 104b is electrically coupled to bit line 112a, word line 110b, and common or ground 114. Phase change memory cell 104c is electrically coupled to bit line 112b, word line 110a, and common or ground 114, and phase change memory cell 104d is electrically coupled to bit line 112b, word line 110b, and common or ground 114.

Each phase change memory cell 104 includes a phase change element 106 and a transistor 108. While transistor 108 is a field-effect transistor (FET) in the illustrated embodiment, in other embodiments, transistor 108 can be another suitable device such as a bipolar transistor or a 3D transistor structure. In other embodiments, a diode or diode-like structure is used in place of transistor 108. In this case, a diode and phase change element 106 is coupled in series between each cross point of word lines 110 and bit lines 112.

Phase change memory cell 104a includes phase change element 106a and transistor 108a. One side of phase change element 106a is electrically coupled to bit line 112a, and the other side of phase change element 106a is electrically coupled to one side of the source-drain path of transistor 108a. The other side of the source-drain path of transistor 108a is electrically coupled to common or ground 114. The gate of transistor 108a is electrically coupled to word line 110a.

Phase change memory cell 104b includes phase change element 106b and transistor 108b. One side of phase change element 106b is electrically coupled to bit line 112a, and the other side of phase change element 106b is electrically coupled to one side of the source-drain path of transistor 108b. The other side of the source-drain path of transistor 108b is electrically coupled to common or ground 114. The gate of transistor 108b is electrically coupled to word line 110b.

Phase change memory cell 104c includes phase change element 106c and transistor 108c. One side of phase change element 106c is electrically coupled to bit line 112b and the other side of phase change element 106c is electrically coupled to one side of the source-drain path of transistor 108c. The other side of the source-drain path of transistor 108c is electrically coupled to common or ground 114. The gate of transistor 108c is electrically coupled to word line 110a.

Phase change memory cell 104d includes phase change element 106d and transistor 108d. One side of phase change element 106d is electrically coupled to bit line 112b and the other side of phase change element 106d is electrically coupled to one side of the source-drain path of transistor 108d. The other side of the source-drain path of transistor 108d is electrically coupled to common or ground 114. The gate of transistor 108d is electrically coupled to word line 110b.

In another embodiment, each phase change element 106 is electrically coupled to a common or ground 114 and each transistor 108 is electrically coupled to a bit line 112. For example, for phase change memory cell 104a, one side of phase change element 106a is electrically coupled to common or ground 114. The other side of phase change element 106a is electrically coupled to one side of the source-drain path of transistor 108a. The other side of the source-drain path of transistor 108a is electrically coupled to bit line 112a.

In one embodiment, each phase change element 106 includes a phase change material that may be made up of a variety of materials. Generally, chalcogenide alloys that contain one or more elements from group VI of the periodic table are useful as such materials. In one embodiment, the phase change material of phase change element 106 is made up of a chalcogenide compound material, such as GeSbTe, SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element 106 may be changed from an amorphous state to a crystalline state or from a crystalline state to an amorphous state under the influence of temperature change. The amount of crystalline material coexisting with amorphous material in the phase change material of one of the phase change elements 106a-106d thereby defines two or more states for storing data within memory chip 102. In the amorphous state, a phase change material exhibits significantly higher resistivity than in the crystalline state. Therefore, the two or more states of phase change elements 106a-106d differ in their electrical resistivity.

In one embodiment, the two or more states are two states and a binary system is used, wherein the two states are assigned bit values of “0” and “1”. In another embodiment, the two or more states are three states and a ternary system is used, wherein the three states are assigned bit values of “0”, “1”, and “2”. In another embodiment, the two or more states are four states that can be assigned multi-bit values, such as “00”, “01”, “10”, and “11”. In other embodiments, the two or more states can be any suitable number of states in the phase change material of a phase change element.

Controller 120 includes a microprocessor, microcontroller, or other suitable logic circuitry for controlling the operation of memory chip 102. Controller 120 controls read and write operations of memory chip 102 including the application of control and data signals to memory array 103 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In another embodiment, sense circuit 126 provides voltage across one of the memory cells 104 and reads the current that flows through that one of the memory cells 104. In another embodiment, write circuit 124 provides voltage across one of the memory cells 104 and sense circuit 126 reads the current that flows through that one of the memory cells 104. In another embodiment, write circuit 124 provides current that flows through one of the memory cells 104 and sense circuit 126 reads the voltage across that one of the memory cells 104.

During a set operation of phase change memory cell 104a, word line 110a is selected to activate transistor 108a. With word line 110a selected, one or more set current or voltage pulses are selectively enabled by write circuit 124 and sent through bit line 112a to phase change element 106a. The set current or voltage pulses heat phase change element 106a above its crystallization temperature (but usually below its melting temperature). In this way, phase change element 106a reaches the crystalline state or a partially crystalline and partially amorphous state during this set operation.

During a reset operation of phase change memory cell 104a, word line 110a is selected to activate transistor 108a. With word line 110a selected, a reset current or voltage pulse is selectively enabled by write circuit 124 and sent through bit line 112a to phase change element 106a. The reset current or voltage pulse quickly heats phase change element 106a above its melting temperature. After the current or voltage pulse is turned off, phase change element 106a quickly quench cools into the amorphous state or a partially amorphous and partially crystalline state. Phase change memory cells 104b-104d and other phase change memory cells 104 in memory array 103 are set and reset similarly to phase change memory cell 104a using similar current or voltage pulses.

FIG. 4 is a block diagram illustrating another embodiment of a memory device 100b. In one embodiment, memory device 100b provides memory device 100 previously described and illustrated with reference to FIG. 1. Memory device 100b includes chips 102a and 102b. In other embodiments, memory device 100b includes another suitable number of chips, such as three or more. Each chip 102a and 102b is electrically coupled to an external device via a chip select line 142 and address lines 144. Chips 102a and 102b are enclosed in packaging material or housing 105.

Each chip 102a and 102b is substantially identical and includes an array of phase change memory cells, a controller, input/output logic, an enable circuit 140, and other suitable circuits for accessing the array of phase change memory cells. Chip 102b is stacked on top of or above chip 102a. Chip select line 142 is electrically coupled to chip select inputs of each chip 102a and 102b in parallel. Therefore, in response to a chip select signal on chip select line 142, both chips 102a and 102b are activated. With both chips 102a and 102b activated, both chips 102a and 102b prepare for reading or writing data.

Address lines 144 are electrically coupled to address inputs and the enable inputs of each chip 102a and 102b in parallel. Address lines (x−1) 144a are electrically coupled to address inputs of each chip 102a and 102b, where “x” indicates a suitable number of address lines based on the storage capacity of the memory device 100b. One address line 144b is electrically coupled to the input of each enable circuit 140 of each chip 102a and 102b. The signal on address line 144b is analyzed by each enable circuit 140 to determine whether the associated chip 102a or 102b is responsible for performing a read or write operation for the given address range. For embodiments including three or more chips, two or more address lines are electrically coupled to the input of each enable circuit of each chip to determine whether the associated chip is responsible for performing a read or write operation for the given address range. In one embodiment, address line 144b is the least significant address line, such as for a performance-optimized memory device where both chips 102a and 102b are active in parallel. In another embodiment, address line 144b is the most significant address line, such as for a power-optimized memory device where only one chip 102a or 102b is active at a time.

For example, in one embodiment, chips 102a and 102b each include a 512 Mb memory array to provide a memory device 100b for storing 1 Gb of data. In this embodiment, address lines 144 include 30 address lines (i.e., x=30) including one address line 144b for selecting chip 102a or 102b for a read or write access. In this way, the size of memory device 100b is doubled while maintaining compatibility with a single chip memory device with respect to data format and access protocols.

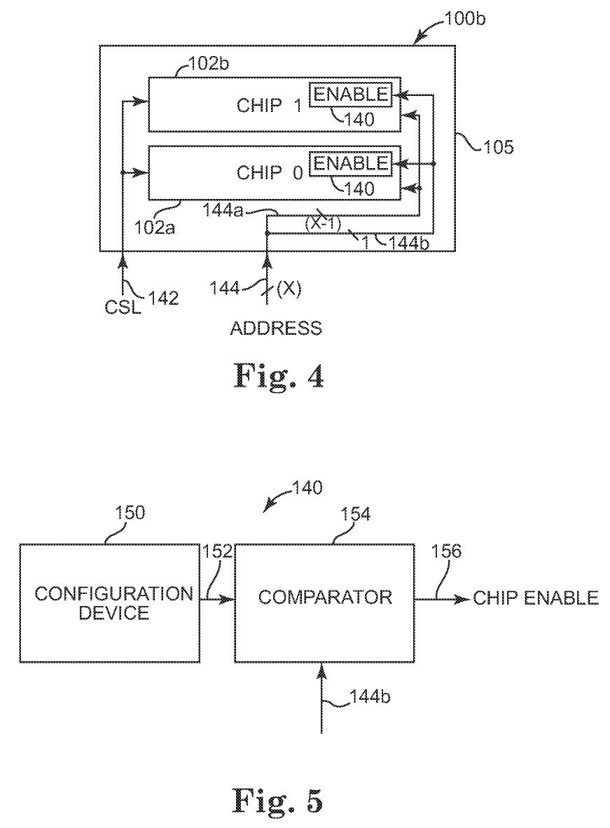

FIG. 5 is a block diagram illustrating one embodiment of a memory chip enable circuit 140. Memory chip enable circuit 140 includes a configuration device 150 and a comparator 154. An output of configuration device 150 is electrically coupled to a first input of comparator 154 through signal path 152. A second input of comparator 154 receives an address signal on address line 144b. The output of comparator 154 provides a chip enable signal on chip enable signal path 156.

Configuration device 150 includes laser fuses, electrical fuses, non-volatile memory cells, or other suitable configuration devices. Configuration device 150 is programmed to identify the chip and the address range for which the chip performs a read or write operation. Configuration device 150 provides the chip identity to comparator 154 through signal path 152.

Comparator 154 compares the signal on signal path 152 to the signal on address line 144b. In response to the signal on signal path 152 matching the signal on address line 144b, comparator 154 outputs the chip enable signal on chip enable signal path 156 to activate the associated chip for a read or write access. In response to the signal on signal path 152 differing from the signal on address line 144b, comparator 154 does not output the chip enable signal on chip enable signal path 156 such that the associated chip is not activated for a read or write access.

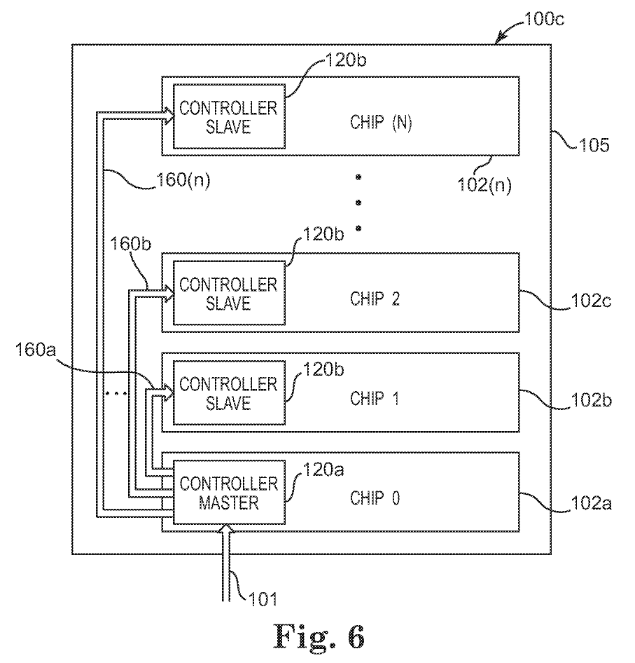

FIG. 6 is a block diagram illustrating another embodiment of a memory device 100c. In one embodiment, memory device 100c provides memory device 100 previously described and illustrated with reference to FIG. 1. Memory device 100c includes chips 102a-102(n). Chip 102a is electrically coupled to an external device via communication path 101. Each chip 102b-102(n) is electrically coupled to chip 102a through a communication path 160a-160(n), respectively. Chips 102a-102(n) are enclosed in packaging material or housing 105.

Each chip 102a-102(n) is substantially identical and includes an array of phase change memory cells, a controller 120a or 120b, input/output logic, and other suitable circuits for accessing the array of phase change memory cells. Controller 120a of chip 102a is configured as a master controller and controllers 120b of chips 102b-102(n) are configured as slave controllers. Each chip 102a-102(n) is on top of or above the previous chip 102a-102(n), such that chip 102b is stacked on top of or above chip 102a, and chip 102c is stacked on top of or above chip 102b. In one embodiment, memory device 100c includes two chips 102a and 102b. In other embodiments, memory device 100c includes any suitable number of chips.

Communication path 101 provides power lines, control lines, address lines, and data lines to chip 102a for providing power, control signals, address signals, and data signals to chip 102a. Chip 102a provides power, control signals, address signals, and data signals to chip 102b through communication path 160a. Chip 102a provides power, control signals, address signals, and data signals to chip 102c through communication path 160b. Chip 102a provides power, control signals, address signals, and data signals to chip 102(n) through communication path 160(n).

Master controller 120a of chip 102a receives all control signals, address signals, and data signals from an external device via communication path 101 and controls all read and write access to chips 102b-102(n). In operation, a host, such as host 92 previously described and illustrated with reference to FIG. 1, accesses memory device 100c through communication path 101. From the perspective of host 92, memory device 100c acts as a single chip memory device and does not require special printed circuit board layouts and/or sideboard connectors. The maximum storage capacity of memory device 100c, however, can be substantially increased compared to a single chip memory device.

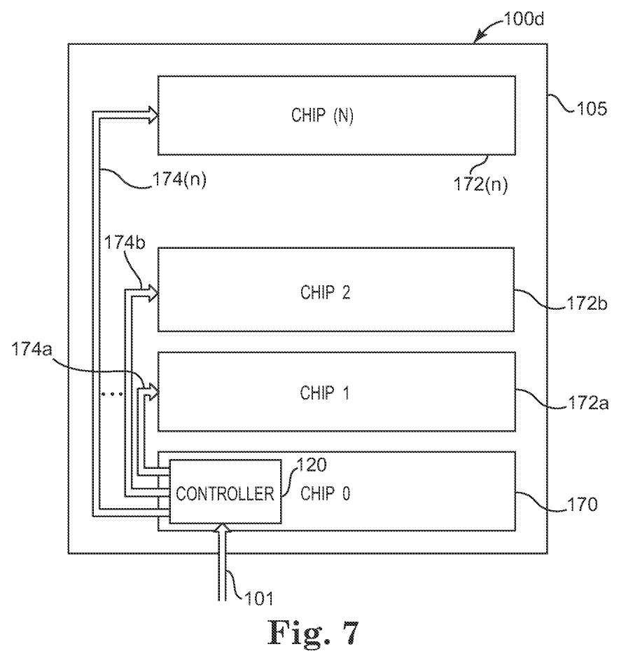

FIG. 7 is a block diagram illustrating another embodiment of a memory device 100d. In one embodiment, memory device 100d provides memory device 100 previously described and illustrated with reference to FIG. 1. Memory device 100d includes chips 170 and 172a-172(n). Chip 170 is electrically coupled to an external device via communication path 101. Each chip 172a-172(n) is electrically coupled to chip 170 through a communication path 174a-174(n), respectively. Chips 170 and 172a-172(n) are enclosed in packaging material or housing 105.

Each chip 172a-172(n) is substantially identical and includes an array of phase change memory cells and other suitable circuits for accessing the array of phase change memory cells. Each chip 172a-172(n) does not include a controller or input/output logic. Chip 170 includes a controller 120 and input/output logic for accessing the array of phase change memory cells within chip 170 and the array of phase change memory cells within each chip 172a-172(n). Each chip 170 and 172a-172(n) is stacked on top of or above the previous chip 172a-172(n), such that chip 172a is stacked on top of or above chip 170, and chip 172b is stacked on top of or above chip 172a. In one embodiment, memory device 100d includes two chips 170 and 172a. In other embodiments, memory device 100d includes any suitable number of chips.

Communication path 101 provides power lines, control lines, address lines, and data lines to chip 170 for providing power, control signals, address signals, and data signals to chip 170. Chip 170 provides power, control signals, address signals, and data signals to chip 172a through communication path 174a. Chip 170 provides power, control signals, address signals, and data signals to chip 172b through communication path 174b. Chip 170 provides power, control signals, address signals, and data signals to chip 172(n) through communication path 174(n).

Controller 120 of chip 170 receives all control signals, address signals, and data signals from an external device via communication path 101 and controls all read and write access to chips 172a-172(n). In operation, a host, such as host 92 previously described and illustrated with reference to FIG. 1, accesses memory device 100d through communication path 101. From the perspective of host 92, memory device 100d acts as a single chip memory device and does not require special printed circuit board layouts and/or sideboard connectors. The maximum storage capacity of memory device 100d, however, can be substantially increased compared to a single chip memory device.

Embodiments provide a stacked die memory device that can be used in place of a single chip memory device without printed circuit board modifications and/or sideboard connectors. The stacked die memory device is compatible with a single chip memory device with respect to data format and access protocols. In this way, the maximum storage capacity of the memory device can be substantially increased without substantially increasing the amount of space used by the memory device.

While the specific embodiments described herein substantially focused on using phase change memory cells, the embodiments can be applied to any suitable type of resistance or resistivity changing memory cells.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory comprising:
a first die including a first array of phase change memory cells;
a second die including a second array of phase change memory cells, the second die stacked above the first die; and
lines configured to access the first die and the second die;
wherein the first die and the second die are enclosed in a single package.

2. The memory of claim 1, wherein the first die is substantially identical to the second die.

3. The memory of claim 2, wherein the lines comprise a chip select line for activating the first array and the second array in response to a chip select signal.

4. The memory of claim 2, wherein the lines comprise address lines for addressing the first array and the second array, and
wherein the first array and the second array are selected for access based on an address signal on one of the address lines.

5. The memory of claim 1, wherein the first die comprises a master controller for communicating with an external device; and
wherein the second die comprises a slave controller for communicating with the master controller; and
wherein the master controller is configured to control all access to the first array and the second array.

6. The memory of claim 1, wherein the first die comprises a controller, the controller configured to control all access to the first array and the second array.

7. The memory of claim 6, wherein the second die does not include a controller.

8. The memory of claim 1, wherein the lines are coupled to the first die and the second die in parallel.

9. The memory of claim 1, further comprising:
at least one additional die including an additional array of phase change memory cells, the at least one additional die stacked above the second die;
wherein the lines are configured to access the at least one additional die, and
wherein the at least one additional die is enclosed in the single package.

10. A system comprising:
a host; and
a memory device communicatively coupled to the host, the memory device comprising:
a first die including a first array of phase change memory cells;
a second die including a second array of phase change memory cells, the second die stacked above the first die;
lines for accessing the first die and the second die; and
a housing enclosing the first die and the second die.

11. The system of claim 10, wherein the first die is substantially identical to the second die.

12. The system of claim 11, wherein the lines comprise a chip select line for activating the first array and the second array in response to a chip select signal.

13. The system of claim 11, wherein the lines comprise address lines for addressing the first array and the second array, and
wherein the first array and the second array are selected for access based on an address signal on one of the address lines.

14. The system of claim 10, wherein the first die comprises a master controller for communicating with the host; and
wherein the second die comprises a slave controller for communicating with the master controller; and
wherein the master controller is configured to control all access to the first array and the second array.

15. The system of claim 10, wherein the first die comprises a controller, the controller configured to control all access to the first array and the second array.

16. A method for fabricating a memory, the method comprising:
fabricating a first die including a first array of phase change memory cells;
fabricating a second die including a second array of phase change memory cells;
stacking the second die above the first die;
fabricating lines for accessing the first die and the second die; and
enclosing the first die and the second die in packaging material.

17. The method of claim 16, wherein fabricating the second die comprises fabricating the second die identical to the first die.

18. The method of claim 17, wherein fabricating lines comprises fabricating a chip select line for activating the first array and the second array in response to a chip select signal.

19. The method of claim 17, further comprising:
configuring the first die with a first identity for accessing the first array in response to a first address within a first address range; and
configuring the second die with a second identity for accessing the second array in response to a second address within a second address range.

20. The method of claim 16, wherein fabricating the first die comprises fabricating the first die including a first controller and wherein fabricating the second die comprises fabricating the second die including a second controller, the method further comprising:
configuring the first controller as a master controller for communicating with an external device and for controlling access to the first array and the second array; and
configuring the second controller as a slave controller for communicating with the master controller.

21. The method of claim 16, wherein fabricating the first die comprises fabricating the first die including a controller configured to control access to the first array and the second array.

22. The method of claim 16, further comprising:
fabricating at least one additional die including an additional array of phase change memory cells; and
stacking the at least one additional die above the second die, and
wherein fabricating the lines comprises fabricating the lines for accessing the at least one additional die.
